(19) United States
(12) Patent Application Publication
(10) Pub. No.: US 2024/0266374 A1
(43) Pub. Date: Aug. 8, 2024

(54) LIGHT DETECTION DEVICE AND ELECTRONIC APPARATUS

(71) Applicant: SONY SEMICONDUCTOR SOLUTIONS CORPORATION, KANAGAWA (JP)

(72) Inventor: TAKASHI TERADA, KUMAMOTO (JP)

(21) Appl. No.: 18/561,181

(22) PCT Filed: Jan. 18, 2022
(86) PCT No.: PCT/JP2022/001573

§ 371 Date: Nov. 15, 2023

(30) Foreign Application Priority Data
Jun. 3, 2021 (JP) 2021-093812

(51) Int. Cl. H01L 27/146; G01S 7/481; G01S 17/894

(52) U.S. Cl. CPC H01L 27/14623; G01S 7/4816; G01S 17/894; H01L 27/14645

(57) ABSTRACT

An object is to improve improvement in reliability. A light detection device includes a semiconductor layer having a photoelectric conversion region defined by an isolation region including a groove, in which the isolation region includes a first portion and a second portion adjacent to each other with the semiconductor layer in between in plan view, the semiconductor layer between the first portion and the second portion includes a first side portion on a side of the first portion and a second side portion on a side of the second portion, and the first side portion and the second side portion are different in planar shape.

### TECHNICAL FIELD

The present technology (a technology according to the present disclosure) relates to a light detection device and an electronic apparatus, in particular, to a light detection device including a semiconductor layer having a photoelectric conversion region defined by an isolation region and an electronic apparatus including the light detection device.

### BACKGROUND ART

In light detection devices such as a solid-state imaging device and a ranging sensor, a photoelectric conversion region of a semiconductor layer is defined by an isolation region. As the isolation region, an isolation region (a trench isolation region) with a trench structure and that is able to electrically and optically isolate adjacent photoelectric conversion regions from each other in a two-dimensional plane is employed. The trench-type isolation region includes a groove made in a semiconductor layer and an embedded film, such as an insulation film or an electrically conductive film, embedded in the groove. The trench-type isolation region is then usually in a lattice planar pattern.

The lattice planar pattern includes an intersection where trench-type isolation regions extending in different directions (for example, X-direction and Y-direction orthogonal to each other) intersect in a two-dimensional plane. In such a lattice planar pattern, a micro-loading effect during the formation of the groove in the semiconductor layer makes a planer size of the intersection more likely to be enlarged than a region other than the intersection. The enlargement of the intersection reduces a planar size of the photoelectric conversion region surrounded by the trench-type isolation regions, affecting a saturated signal amount Qs. In addition, the enlargement of the intersection becomes notable with a depth of the trench-type isolation regions.

Accordingly, PTL 1 discloses a lattice planar pattern with an intersection eliminated structure in which, for example, a trench-type isolation region extending in an X-direction and a trench-type isolation region extending in a Y-direction are spaced to eliminate an intersection in a two-dimensional plane.

### CITATION LIST

### Patent Literature

### [PTL 1]

Japanese Patent Laid-Open No. 2021-34598

### SUMMARY

### Technical Problem

In the meanwhile, a lattice planar pattern with an intersection eliminated structure requires a reduction in color mixing between photoelectric conversion regions adjacent with a trench-type isolation region extending in a Y-direction in between. The reduction in color mixing requires miniaturizing a semiconductor layer between an X-directional trench-type isolation region and a Y-directional trench-type isolation region to decrease a distance of a space between the X-directional trench-type isolation region and the Y-directional trench-type isolation region.

However, a mechanical strength of the semiconductor layer between the X-directional trench-type isolation region and the Y-directional trench-type isolation region is lowered due to the miniaturization. That is, the miniaturization and the mechanical strength of the semiconductor layer between the X-directional trench-type isolation region and the Y-directional trench-type isolation region are in a trade-off relation and there is room for improvement in terms of reliability.

An object of the present technology is to improve reliability.

### Solution to Problem

(1) A light detection device according to an aspect of the present technology includes a semiconductor layer having a photoelectric conversion region defined by an isolation region including a groove. Then, the isolation region includes a first portion and a second portion adjacent to each other with the semiconductor layer in between in plan view, the semiconductor layer between the first portion and the second portion includes a first side portion on a side of the first portion and a second side portion on a side of the second portion, and the first side portion and the second side portion are different in shape in cross-sectional view.
(2) A light detection device according to another aspect of the present technology includes a semiconductor layer having a photoelectric conversion region defined by an isolation region including a groove, and two transfer transistors provided in the photoelectric conversion region. Then, the isolation region includes a first portion and a second portion adjacent to each other with the semiconductor layer in between in plan view, the semiconductor layer between the first portion and the second portion includes a first side portion on a side of the first portion and a second side portion on a side of the second portion, and the first side portion and the second side portion are different in shape in cross-sectional view.
(3) An electronic apparatus according to still another aspect of the present technology includes the light detection device.

### BRIEF DESCRIPTION OF DRAWINGS

FIG. 1 is a chip-layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is a schematic cross-sectional view illustrating a cross-sectional structure of a pixel array portion.

FIG. 4 is a schematic plan view illustrating a planar pattern of an isolation region of the pixel array portion.

FIG. 5 is a schematic plan view illustrating a first planar pattern included in the planar pattern in FIG. 4.

FIG. 6 is a schematic cross-sectional view illustrating a cross-sectional structure taken along a II-II line in FIG. 5.

FIG. 7 is a schematic plan view illustrating a second planar pattern included in the planar pattern in FIG. 4.

FIG. 8 is a schematic cross-sectional view illustrating a cross-sectional structure taken along a III-III line in FIG. 7.

FIG. 9 is a schematic cross-sectional view of a relevant part, illustrating a modification example of the first embodiment.

FIG. 10 is a schematic plan view of a relevant part, illustrating the modification example of the first embodiment.

FIG. 11 is a block diagram illustrating a configuration example of a ranging sensor according to a second embodiment of the present technology.

FIG. 12 is a schematic cross-sectional view of a relevant part, illustrating a configuration example of a pixel mounted in the ranging sensor according to the second embodiment of the present technology.

FIG. 13 is a diagram illustrating an equivalent circuit of the pixel mounted in the ranging sensor according to the second embodiment of the present technology.

FIG. 14 is a schematic cross-sectional view of a relevant part, illustrating a modification example of the second embodiment.

FIG. 15 is a schematic plan view of a relevant part, illustrating a configuration example of a pixel mounted in a solid-state imaging device according to a third embodiment of the present technology.

FIG. 16 is a diagram illustrating a configuration example of an electronic apparatus according to a fourth embodiment of the present technology.

FIG. 17 is a diagram illustrating a configuration example of an electronic apparatus according to a fifth embodiment of the present technology.

### DESCRIPTION OF EMBODIMENTS

A detailed description will be made below on embodiments of the present technology with reference to the drawings.

In illustration in the drawings referred to in the following description, the same or similar signs are used to refer to the same or similar parts. Incidentally, note that the drawings are schematic and a relation between thickness and planar dimension, a ratio of a thickness of each layer, and the like are different from actual ones. Accordingly, specific thicknesses and dimensions should be determined in consideration of the following description.

In addition, there is, of course, a part that is different in dimensional relation or ratio between the drawings. In addition, an effect described herein is merely by way of example and not limiting and another effect may be possible.

In addition, the following embodiments merely exemplify a device and a method that implement the technical idea of the present technology and are not intended to specify the configuration to those described below. That is, a variety of modifications are addable to the technical idea of the present technology without departing from the technical scope according to claims.

In addition, definitions of directions, such as up and down, hereinafter are merely definitions for convenience of explanation and are not intended to limit the technical scope of the present technology. For example, when a target is observed as rotated by 90 degrees, up and down is read as translated into right and left and the target is observed as rotated by 180 degrees, up and down is read as reversed.

In addition, in the following embodiments, out of three directions orthogonal to each other in a space, a first direction and a second direction orthogonal to each other in the same plane are referred to as an X-direction and a Y-direction, respectively, and a third direction orthogonal to each of the first direction and the second direction is referred to as a Z-direction. Then, in the following embodiments, description will be made with the assumption that a thickness direction (a depth direction) of a later-described semiconductor layer 20 is the Z-direction.

### First Embodiment

In the first embodiment, description will be made on an example where the present technology is applied to a light detection device in a form of a solid-state imaging device that is a back-illuminated CMOS (Complementary Metal Oxide Semiconductor) image sensor.

### Overall Configuration of Solid-State Imaging Device

First, description will be made on an overall configuration of a solid-state imaging device 1A.

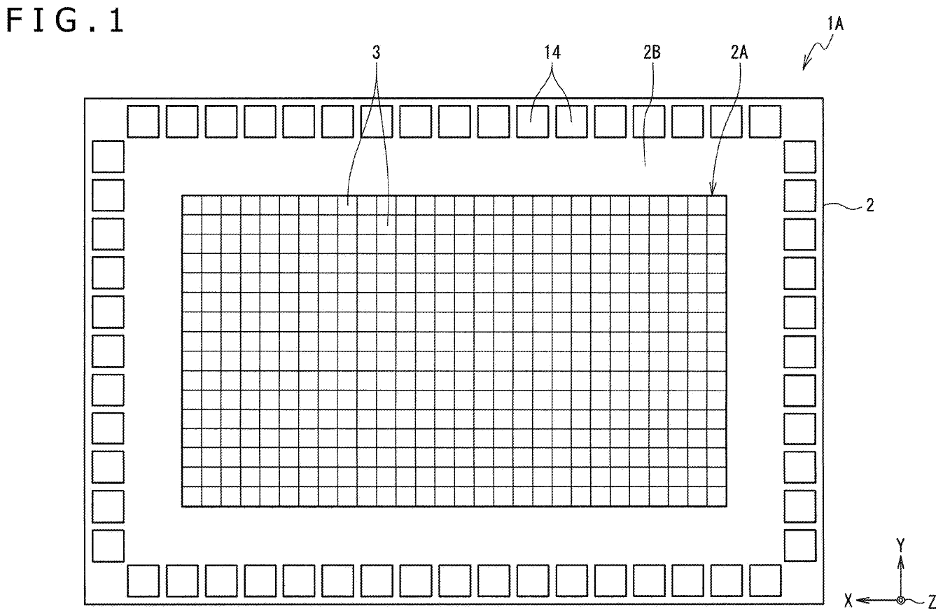

As illustrated in FIG. 1, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2. As illustrated in FIG. 16, the solid-state imaging device 1A (201) lets in image light (incoming light 206) from a subject through an optical lens 202, converts a light amount of the incoming light 206 formed as an image on an imaging plane to an electrical signal on a pixel-by-pixel basis, and outputs the electrical signal as a pixel signal.

As illustrated in FIG. 1, the semiconductor chip 2 on which the solid-state imaging device 1A is mounted includes, in a two-dimensional plane including an X-direction and a Y-direction orthogonal to each other, a rectangular pixel array portion 2A provided at a middle portion and a peripheral portion 2B provided outside the pixel array portion 2A to surround the pixel array portion 2A.

The pixel array portion 2A is a light-receiving surface that receives light collected through, for example, the optical lens (an optical system) 202 illustrated in FIG. 16. Then, in the pixel array portion 2A, multiple pixels 3 are arranged in rows and columns in the two-dimensional plane including the X-direction and the Y-direction. In other words, the pixels 3 are repeatedly arranged in each of the X-direction and the Y-direction orthogonal to each other in the two-dimensional plane.

As illustrated in FIG. 1, multiple bonding pads 14 are disposed in the peripheral portion 2B. The multiple bonding pads 14 are each arranged along, for example, each of four sides of the semiconductor chip 2 in the two-dimensional plane. The multiple bonding pads 14 are each an input/output terminal used to electrically connect the semiconductor chip 2 to an external device.

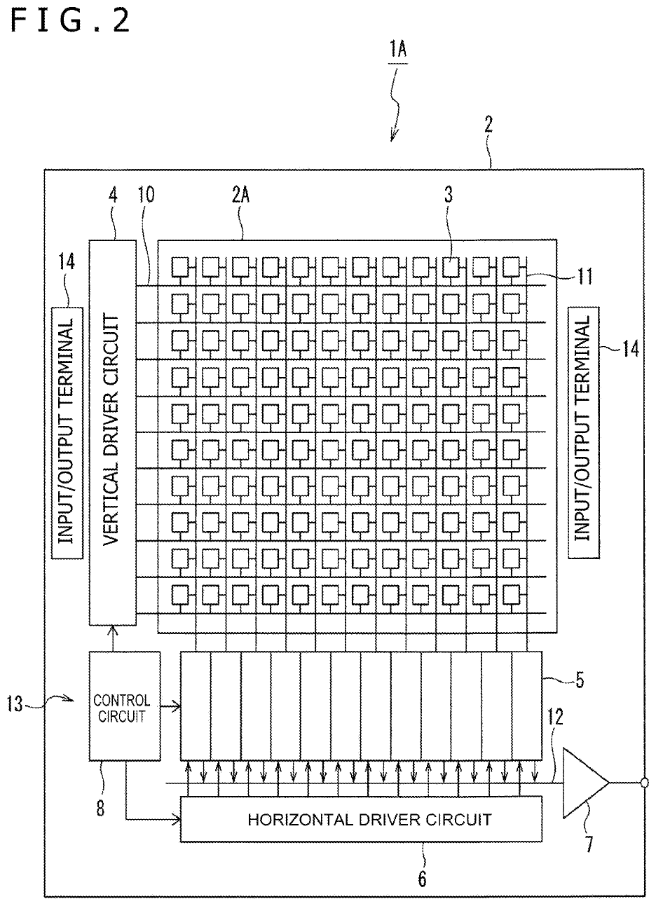

The semiconductor chip 2 includes a logic circuit 13 illustrated in FIG. 2. The logic circuit 13 includes a vertical driver circuit 4, a column signal processing circuit 5, a horizontal driver circuit 6, an output circuit 7, a control circuit 8, and the like as illustrated in FIG. 2. The logic circuit 13 includes, for example, a CMOS (Complementary MOS) circuit as a field-effect transistor, the CMOS circuit including an n-channel conductive MOSFET (Metal Oxide Semiconductor Field Effect Transistor) and a p-channel conductive MOSFET.

The vertical driver circuit 4 includes, for example, a shift resistor. The vertical driver circuit 4 sequentially selects a desired pixel drive line 10, supplies a pulse for driving the pixels 3 to the selected pixel drive line 10, and drives the individual pixels 3 on a row-by-row basis. That is, the vertical driver circuit 4 sequentially performs selective scanning of the individual pixels 3 in the pixel array portion 2A in a vertical direction on a row-by-row basis and supplies pixel signals from the pixels 3 based on signal charges, which are generated depending on amounts of light received by respective photoelectric conversion elements of the pixels 3, to the column signal processing circuit 5 through a vertical signal line 11.

The column signal processing circuit 5 is disposed for, for example, each column of the pixels 3 and applies signal processing, such as denoising, to the signals outputted from the pixels 3 in one column on a pixel-by-pixel basis. For example, the column signal processing circuit 5 performs signal processing such as CDS (Correlated Double Sampling) and AD (Analog Digital) conversion for removing a pixel-specific fixed pattern noise.

The horizontal driver circuit 6 includes, for example, a shift resistor. The horizontal driver circuit 6 sequentially outputs horizontal scanning pulses to the column signal processing circuits 5, thereby selecting each of the column signal processing circuits 5 in order and causing each of the column signal processing circuits 5 to output signal-processed pixel signals to the horizontal signal line 12.

The output circuit 7 applies signal processing to the pixel signals sequentially supplied through the horizontal signal line 12 from each of the column signal processing circuits 5 and outputs the pixel signals. For example, buffering, black-level adjustment, column variation correction, a variety of digital signal processing, and the like are usable as the signal processing.

The control circuit 8 generates a clock signal and a controls signal, which are the basis of operations of the vertical driver circuit 4, the column signal processing circuit 5, the horizontal driver circuit 6, and the like, on the basis of a vertical synchronization signal, a horizontal synchronization signal, and a master lock signal. The control circuit 8 then outputs the generated clock signal and the control signal to the vertical driver circuit 4, the column signal processing circuit 5, the horizontal driver circuit 6, and the like.

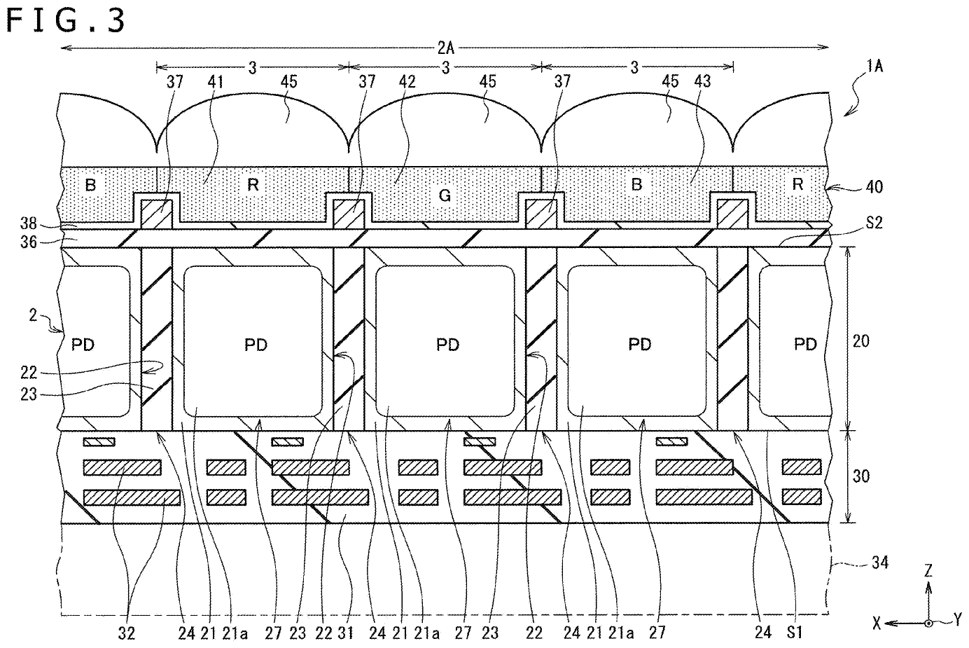

Each of the multiple pixels 3 includes a photoelectric conversion region 27 illustrated in FIG. 3 and a non-illustrated plurality of pixel transistors. For example, four transistors, which are a transfer transistor, a reset transistor, a selection transistor, and an amplification transistor, are usable as the multiple pixel transistors. Alternatively, for example, three of the transistors excluding the selection transistor may be used as the multiple pixel transistors.

### Specific Configuration of Solid-State Imaging Device

Next, description will be made on a specific configuration of the solid-state imaging device 1A.

As illustrated in FIG. 3, the semiconductor chip 2 includes the semiconductor layer 20 in which the multiple photoelectric conversion regions 27 are provided, and a color filter layer 40 disposed on, out of a first surface S1 and a second surface S2 of the semiconductor layer 20 located opposite each other in a thickness direction (a Z-direction), a side of the second surface S2, or a side of light entrance surface.

In addition, the semiconductor chip 2 further includes multiple microlenses 45 (on-chip lenses, wafer lenses) disposed on a side of a light entrance surface of the color filter layer 40 (an opposite side to the side of the semiconductor layer 20).

In addition, the semiconductor chip 2 further includes a multilayer wiring layer 30 disposed on a side of the first surface S1 of the semiconductor layer 20, and a support substrate 34 disposed on an opposite side to the side of the semiconductor layer 20 of the multilayer wiring layer 30.

The semiconductor layer 20 includes, for example, a p-type semiconductor substrate including monocrystalline silicon. The multiple photoelectric conversion regions 27 are arranged in rows in the pixel array portion 2A, corresponding one-to-one to the multiple respective pixels 3. The photoelectric conversion regions 27 are then defined by an isolation region 24 provided in the semiconductor layer 20. The isolation region 24 extends from the side of the second surface S2 toward the side of the first surface S1 of the semiconductor layer 20, electrically and optically isolating the photoelectric conversion regions 27 adjacent to each other in plan view. The isolation region 24 includes a groove 22 extending from the side of the second surface S2 toward the side of the first surface S1 of the semiconductor layer 20 and an insulation film 23 embedded in the groove 22. For example, a silicon oxide film is usable as the insulation film 23. The isolation region 24 of the first embodiment extends, without limitation, across between the second surface S2 and the first surface S1 of the semiconductor layer 20.

Here, the first surface S1 of the semiconductor layer 20 is occasionally referred to as an element formation surface or a principal surface and the side of the second surface S2 as a light entrance surface or a back surface. The solid-state imaging device 1A of the first embodiment causes light entering from the side of the second surface (the light entrance surface, the back surface) S2 of the semiconductor layer 20 to be photoelectrically converted through the photoelectric conversion regions 27 provided in the semiconductor layer 20.

In addition, “in plan view” refers to a case of being viewed from a direction along the thickness direction of the semiconductor layer 20 (the Z-direction). In addition, “in cross-sectional view” refers to a case where a cross section along the thickness direction of the semiconductor layer 20 (the Z-direction) is viewed from a direction (the X-direction or the Y-direction) orthogonal to the thickness direction of the semiconductor layer 20 (the Z-direction).

It should be noted that a sandwich structure where a metal film is sandwiched by insulation films on opposite sides in the groove 22 is also usable as the isolation region 24.

As illustrated in FIG. 3, each of the multiple photoelectric conversion regions 27 includes, for example, a p-type well region 21 including a p-type semiconductor region and an n-type semiconductor region 21a. In addition, each of the multiple photoelectric conversion regions 27 includes, for example, a photodiode (PD) element, which is not illustrated in detail, as the photoelectric conversion element and further includes a transfer transistor. That is, in the pixel array portion 2A, the multiple pixels 3, which include the photoelectric conversion elements and the transfer transistors embedded in the semiconductor layer 20, are arranged in rows and columns (in a two-dimensional matrix). In the photoelectric conversion regions 27, a signal charge is generated depending on the light amount of incoming light and the generated signal charge is accumulated. The n-type semiconductor region 21a is provided in the p-type well region 21. The photodiode PD includes the p-type well region 21 and the n-type semiconductor region 21a.

As illustrated in FIG. 3, the multilayer wiring layer 30, which is disposed on the side of the first surface S1 opposite to the side of the light entrance surface (the second surface S2) of the semiconductor layer 20, includes multiple wiring layers including wiring lines 32 and that are stacked in multiple tiers with an interlayer insulation film 31 in between. The pixel transistors of the pixels 3 are driven through the wiring lines 32 in the wiring layers. The multilayer wiring layer 30 is disposed on the opposite side to the side of the light entrance surface (the side of the second surface S2) of the semiconductor layer 20, which makes it possible to flexibly set a layout of the wiring lines 32.

The color filter layer 40 includes, but not limited to, for example, first color filter section 41 for red (R), a second color filter section 42 for green (G), and a third color filter section 43 for blue (B). The first to third color filter sections 41 to 43 are arranged in rows and columns in the pixel array portion 2A to correspond one-to-one to the multiple pixels 3, that is, each of the multiple photoelectric conversion regions 27. The first to third color filter sections 41 to 43 are configured to transmit specific wavelengths of incoming light desired to be received by the photoelectric conversion regions 27 and cause the transmitted incoming light to enter the photoelectric conversion regions 27.

The multiple microlenses 45 are arranged in rows and columns in the pixel array portion 2A to correspond one-to-one to the multiple pixels 3, that is, the multiple photoelectric conversion regions 27. The microlenses 45 collect irradiation light and cause the collected light to efficiently enter the photoelectric conversion regions 27 of the semiconductor layer 20 through the color filter layer 40. The multiple microlenses 45 form a microlens array on a side of the light entrance surface of the color filter layer 40.

The support substrate 34 is provided on a surface of the multilayer wiring layer 30 opposite to a side facing the semiconductor layer 20. The support substrate 34 is a substrate for securing a strength of the semiconductor layer 20 at a stage of manufacturing the solid-state imaging device 1A. For example, silicon (Si) is usable as a material of the support substrate 34.

As illustrated in FIG. 3, a flattened film 36, a light-shielding film 37, and a sticky film 38 are stacked in this sequence from the side of the semiconductor layer 20 between the semiconductor layer 20 and the color filter layer 40.

The flattened film 36 fully covers the side of the light entrance surface of the semiconductor layer 20 in the pixel array portion 2A to cause the side of the light entrance surface of the semiconductor layer 20 to become a flat surface with no unevenness. For example, a silicon oxide (SiO₂) film is usable as the flattened film 36.

A planar pattern of the light-shielding film 37 in plan view is a lattice planar pattern that causes the multiple photoelectric conversion regions 27 to be open on sides of respective light-receiving surfaces such that no light of a predetermined one of the pixels 3 leaks into the adjacent pixel 3. For example, a tungsten (W) film is used as the light-shielding film 37.

The sticky film 38 is disposed between the flattened film 36 and the light-shielding film 37 and the color filter layer 40 and mainly enhances an adhesiveness between the light-shielding film 37 and the color filter layer 40. For example, a silicon oxide film is used as the sticky film 38.

In the solid-state imaging device 1A having the above-described configuration, light is applied from the side of the microlenses 45 of the semiconductor chip 2, the applied light is transmitted through the microlenses 45 and the color filter sections 41, 42, and 43, individually, and the transmitted light is photoelectrically converted through the photoelectric conversion regions 27 to generate signal charges. The generated signal charges are then outputted as pixel signals through the vertical signal line 11, which includes the wiring lines 32 of the multilayer wiring layer 30, via the pixel transistors formed on the side of the first surface S1 of the semiconductor layer 20. In addition, a distance to a subject is calculated on the basis of a difference between the signal charges generated through the photoelectric conversion regions 27.

### Isolation Region and Photoelectric Conversion Region

Next, description will be made on a specific configuration of the isolation region 24 and the photoelectric conversion region 27.

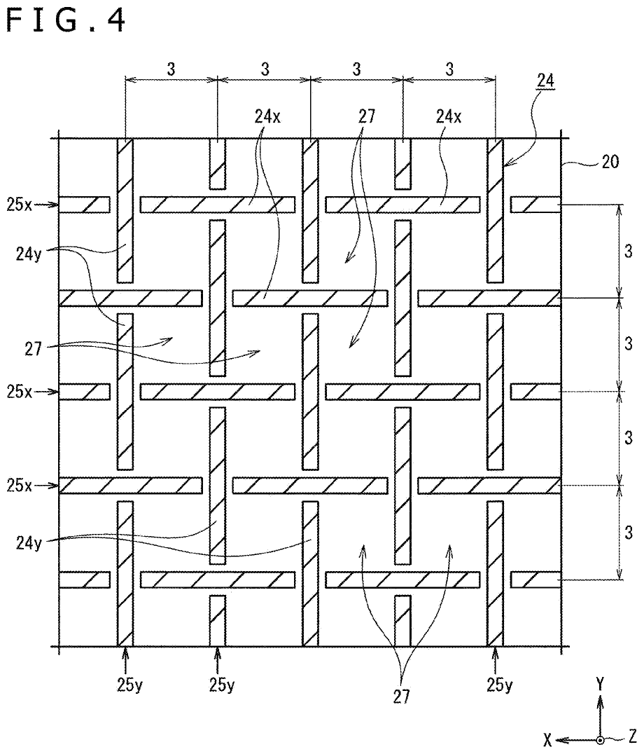

As illustrated in FIG. 4, the isolation region 24 includes, in plan view, first portions 24x extending in the X-direction and second portions 24y extending in the Y-direction. Respective extension directions of the first portions 24x and the second portions 24y are orthogonal to each other. The multiple photoelectric conversion regions 27 are each defined by two of the second portions 24y of the isolation region 24 on X-directional opposite end sides and defined by two of the first portions 24x of the isolation region 24 on Y-directional opposite end sides. The first portions 24x and the second portions 24y included in the isolation region 24 each extend across the second surface S2 and the first surface S1 of the semiconductor layer 20. Then, the first portions 24x and the second portions 24y each include the groove 22 extending across the second surface S2 and the first surface S1 of the semiconductor layer 20 and the insulation film 23 embedded in the groove 22.

In the isolation region 24, the first portions 24x are repeatedly arranged in the X-direction at predetermined intervals in plan view as illustrated in FIG. 4. The multiple first portions 24x repeatedly arranged in the X-direction then form X-directional isolation arrays 25x. The X-directional isolation arrays 25x are repeatedly arranged in the Y-direction at predetermined intervals in plan view. A Y-direction arrangement pitch of the X-directional isolation arrays 25x is the same in design value as a Y-direction arrangement pitch of the photoelectric conversion regions 27. The X-directional isolation arrays 25x are each disposed between two of photoelectric conversion arrays extending in the X-direction with the inclusion of the multiple photoelectric conversion regions 27 arranged in the X-direction. The first portions 24x are arranged every two of the photoelectric conversion regions 27 lying side by side in the X-direction, extending across the two photoelectric conversion regions 27.

In the isolation region 24, the second portions 24y are repeatedly arranged in the Y-direction at predetermined intervals in plan view as illustrated in FIG. 4. The multiple second portions 24y repeatedly arranged in the y-direction then form Y-directional isolation arrays 25y. The Y-directional isolation arrays 25y are repeatedly arranged in the X-direction at predetermined intervals in plan view. An X-direction arrangement pitch of the Y-directional isolation arrays 25y is the same in design value as an X-direction arrangement pitch of the photoelectric conversion regions 27. The Y-directional isolation arrays 25y are each disposed between two of photoelectric conversion arrays extending in the Y-direction with the inclusion of the multiple photoelectric conversion regions 27 arranged in the Y-direction. The second portions 24y are arranged every two of the photoelectric conversion regions 27 lying side by side in the Y-direction, extending across the two photoelectric conversion regions 27.

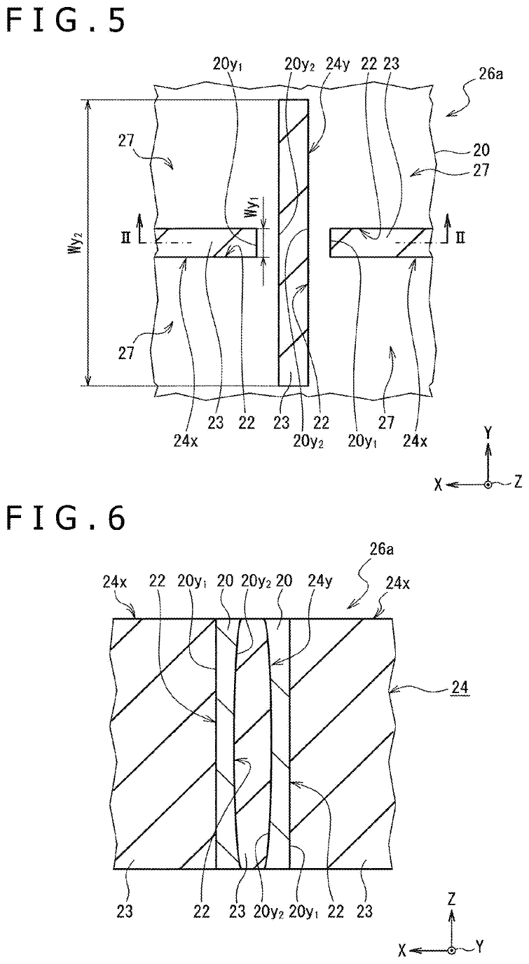

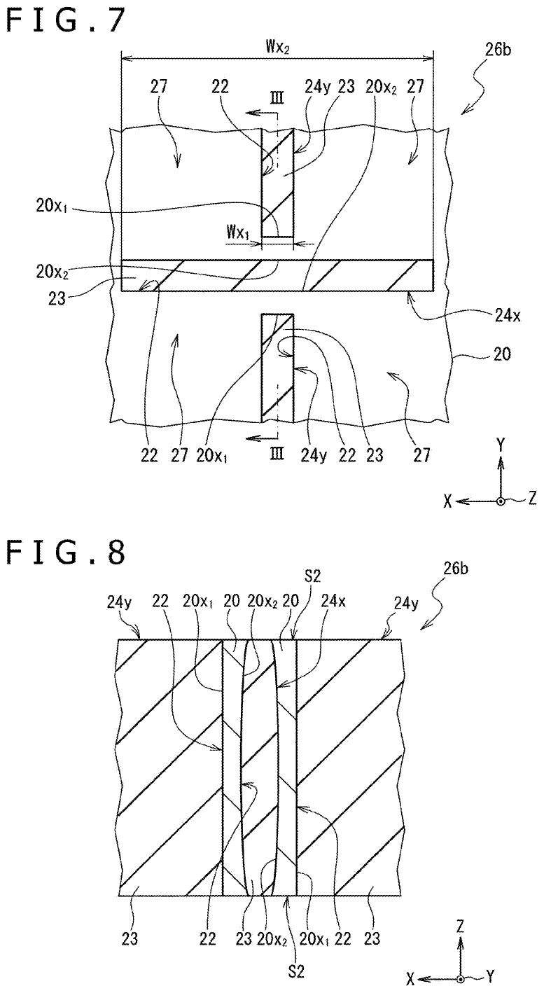

In the isolation region 24, the first portions 24x and the second portions 24y are adjacent to each other with the semiconductor layer 20 in between in plan view as illustrated in FIG. 4. In other words, the first portions 24x and the second portions 24y are opposed to each other with the semiconductor layer 20 in between in plan view. That is, the isolation region 24 includes the first portions 24x and the second portions 25y adjacent to each other with the semiconductor layer 20 in between in plan view. The isolation region 24 then includes, as planar patterns causing the first portions 24x and the second portions 24y to be adjacent to each other with the semiconductor layer 20 in between, a first planar pattern 26a illustrated in FIG. 5 and a second planar pattern 26b illustrated in FIG. 7.

In the first planar pattern 26a, longitudinal directional (X-directional) ends of the first portions 24x are opposed to longitudinal directional (Y-directional) intermediate portions of the second portions 24y with the semiconductor layer 20 in between as illustrated in FIG. 5. The first portions 24x are then spaced from the second portions 24y on lateral directional (width directional: X-directional) opposite sides of the second portions 24y in plan view.

In the second planar pattern 26b, longitudinal directional (Y-directional) ends of the second portions 24y are opposed to longitudinal directional (X-directional) intermediate portions of the first portions 24x with the semiconductor layer 20 in between as illustrated in FIG. 7. The second portions 24y are then spaced from the first portions 24x on lateral directional (width directional: Y-directional) opposite sides of the first portions 24x in plan view.

As illustrated in FIG. 5, two of the photoelectric conversion regions 27 lying side by side in the Y-direction with the first portion 24x of the isolation region 24 in between in plan view are coupled to each other through the semiconductor layer 20 between the longitudinal directional end of the first portion 24x and the longitudinal directional intermediate portion of the second portion 24y.

In addition, as illustrated in FIG. 7, two of the photoelectric conversion regions 27 lying side by side in the X-direction with the second portion 24y of the isolation region 24 in between in plan view are coupled to each other through the semiconductor layer 20 between the longitudinal directional end of the second portion 24y and the longitudinal directional intermediate portion of the first portion 24x. That is, the multiple photoelectric conversion regions 27 are each defined by two of the second portions 24y of the isolation region 24 on the X-directional opposite end sides and defined by two of the first portions 24x of the isolation region 24 on the Y-directional opposite end sides as illustrated in FIG. 4. The isolation region 24 is then in a lattice planar pattern with an intersection eliminated structure in which the first portions 24x extending in the X-direction and the second portions 24y extending in the Y-direction are then spaced from each other in plan view to eliminate intersections where the first portions 24x and the second portions 24y intersect.

In the first pattern 26a, the semiconductor layer 20 between the first portions 24x and the second portions 24y of the isolation region 24 has first side portions 20y₁ on a side of the first portions 24x and second side portions 20y₂ on a side of the second portions 24y as illustrated in FIG. 5 and FIG. 6.

As illustrated in FIG. 5, a width Wy₂ of the second side portions 20y₂, which is the same in direction as a Y-directional width Wy₁ of the first side portions 20y₁, is wider than the width Wy₁ of the first side portions 20y₁ in plan view. The Y-directional width Wy₁ of the first side portions 20y₁ is defined by a Y-directional width of the first isolation portions 24x and the Y-directional width Wy₂ of the second side portions 20y₂ is defined by a Y-directional length of the second portions 24y.

Then, the first side portions 20y₁ and the second side portions 20y₂ have different surface shapes as illustrated in FIG. 6. In the first embodiment, the first side portions 20y₁ are formed in a planar shape and the second side portions 20y₂ are formed in a curved shape. In addition, in the first embodiment, the curved shape of the second side portions 20y₂ is a recessed shape in which the second side portions 20y₂ are recessed toward the first side portions 20y₁. The planar shape of the first side portions 20y₁ and the curved shape of the second side portions 20y₂ can be formed by devising etching type and conditions for machining the grooves 22 of the isolation region 24 in the semiconductor layer 20. In particular, in a case where the width Wy₂ of the second side portions 20y₂ is wider than the width Wy1 of the first side portions 20y₁, it is possible to easily cause the second side portions 20y₂ to be in a curved shape as compared with the first side portions 20y₁.

In the second pattern 26b, the semiconductor layer 20 between the first portions 24x and the second portions 24y of the isolation region 24 has first side portions 20x₁ on a side of the second portions 24y and second side portions 20x₂ on a side of the first portions 24x as illustrated in FIG. 7 and FIG. 8.

As illustrated in FIG. 7, a width Wx₂ of the second side portions 20x₂, which is the same in direction as an X-directional width Wx₁ of the first side portions 20x₁, is wider than the width Wx₁ of the first side portions 20x₁ in plan view. The X-directional width Wx₁ of the first side portions 20x₁ is defined by an X-directional width of the second isolation portions 24y and the X-directional width Wx₂ of the second side portions 20x₂ is defined by an X-directional length of the first portions 24x.

Then, the first side portions 20x₁ and the second side portions 20x₂ have different surface shapes as illustrated in FIG. 8. In the first embodiment, the first side portions 20x₁ are formed in a planar shape and the second side portions 20x₂ are formed in a curved shape as in the first pattern 26a. Then, the curved shape of the second side portions 20x₂ is a recessed shape in which the second side portions 20x₂ are recessed toward the first side portions 20x₁ as in the first pattern 26a. The planar shape of the first side portions 20x₁ and the curved shape of the second side portions 20x₂ can be formed by devising etching type and conditions for machining the grooves 22 of the isolation region 24 in the semiconductor layer 20.

### Main Effects of First Embodiment

Next, description will be made on main effects of the first embodiment.

As illustrated in FIG. 4, the isolation region 24 of the solid-state imaging device 1A according to the first embodiment is in a lattice planar pattern in which the first portions 24x extending in the X-direction and the second portions 24y extending in the Y-direction are spaced from each other in plan view with intersections between the first portions 24x and the second portions 24y being eliminated. Thus, in the isolation region 24 of the first embodiment, it is possible to reduce a reduction in planar size of the photoelectric conversion regions 27 due to an influence of a micro-loading effect during the formation of the grooves 22 of the isolation region 24 in the semiconductor layer 20, which allows for an improvement in saturated signal amount Qs.

In addition, since the isolation region 24 is in the lattice planar pattern with elimination of intersections, concentration of stress on a film embedded in the groove 22 can be relieved to reduce film cracking or the like, which allows for an improvement in reliability.

In addition, in the first planar pattern 26a, the semiconductor layer 20 between the first portions 24x and the second portions 24y of the isolation region 24 has the first side portions 20y₁ on the side of the first portions 24x and the second side portions 20y₂ on the side of the second portions 24y, which are different in surface shape as illustrated in FIG. 6. In addition, in the second planar pattern 26b, the semiconductor layer 20 between the second portions 24y and the first portions 24x of the isolation region 24 has the first side portions 20x₁ on the side of the second portions 24y and the second side portions 20x₂ on the side of the first portions 24x, which are different in flat shape as illustrated in FIG. 8. In the first embodiment, the first side portions 20y₁ and 20x₁ are in a planar shape and the second side portions 20y₂ and 20x₂ are in a recessed curved shape. Thus, as compared with in a case where the first side portions 20y₁ and 20x₁ and the second side portions 20y₂ and 20x₂ of the semiconductor layer 20 are both in a recessed curved shape, it is possible to enhance a mechanical strength of the semiconductor layer 20 between the first portions 24x and the second portions 24y of the isolation region 24. This makes it possible to further improve the reliability and accelerate miniaturization of the photoelectric conversion regions 27 with the mechanical strength of the semiconductor layer 20 between the first portions 24x and the second portions 24y of the isolation region 24 being secured.

In addition, the second side portions 20y₂ and 20x₂ of the semiconductor layer 20 between the first portions 24x and the second portions 24y of the isolation region 24 are in a curved shape, which makes it possible to weaken the periodicity of transmitted light transmitted through the second side portions 20y₂ and 20x₂ to reduce color mixing.

It should be noted that, in the above-described first embodiment, description is made on the case where the second side portions 20y₂ and 20x₂ of the semiconductor layer 20 between the first portions 24x and the second portions 24y of the isolation region 24 are formed in a recessed curved shape. However, the present technology is not limited to the above-described first embodiment. For example, the first side portions 20y₁ and 20x₁ of the semiconductor layer 20 between the first portions 24x and the second portions 24y of the isolation region 24 may be formed in a recessed curved shape and the second side portions 20y₂ and 20x₂ may be formed in a planar shape. In addition, the first side portions 20y₁ and 20x₁ and the second side portions 20y₂ and 20x₂ may be both formed in curved shapes different in flatness. In short, the first side portions 20y₁ and 20x₁ and the second side portions 20y₂ and 20x₂ are formed in different shapes.

In addition, in the above-described first embodiment, description is made on the case where the second side portions 20y₂ and 20x₂ are formed in a recessed curved shape, however, the second side portions 20y₂ and 20x₂ may be formed in a protruding curved shape.

### Modification Examples of First Embodiment

### Modification Example 1-1

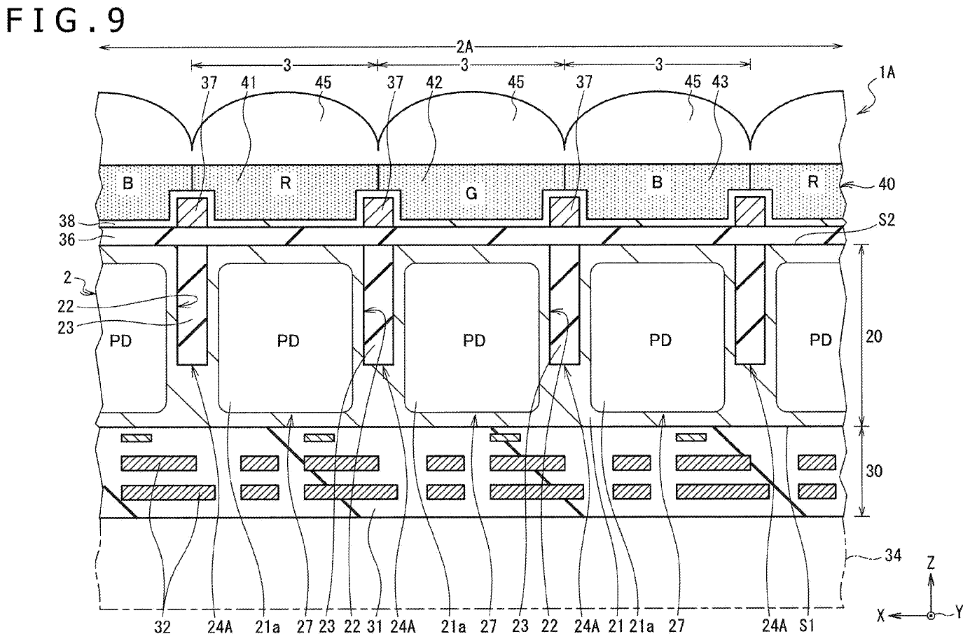

In the above-described first embodiment, description is made on the isolation region 24 extending across the second surface S2 and the first surface S1 of the semiconductor layer 20. However, the present technology is not limited to the isolation region 24 illustrated in FIG. 3 of the above-described first embodiment. For example, as illustrated in FIG. 9, the present technology is also applicable to an isolation region 24A extending from the side of the second surface S2 toward the side of the first surface S1 of the semiconductor layer 20 and spaced from the first surface S1. A depth of the isolation region 24A in this case is smaller than a thickness of the semiconductor layer 20.

In addition, although illustration is omitted, the present technology is also applicable to an isolation region, inversely to the isolation region 24A illustrated in FIG. 9, extending from the side of the first surface S1 toward the side of second surface S2 of the semiconductor layer 20 and spaced from the second surface S2. In this case, a depth of the isolation region 24A is also smaller than the thickness of the semiconductor layer 20.

### Modification Example 1-2

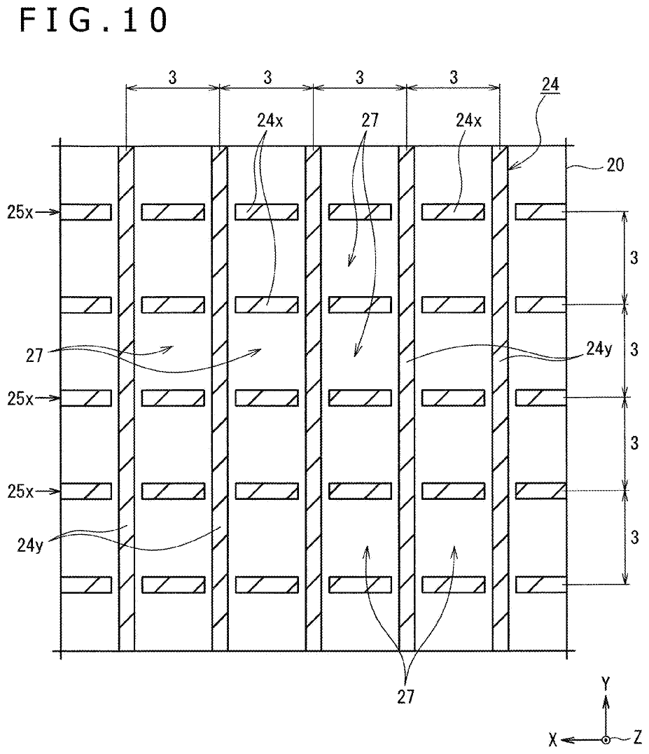

In the above-described first embodiment, description is made on the lattice planar pattern with the intersection eliminated structure in which the first portions 24x of the isolation region 24 are repeatedly arranged in the X-direction at the predetermined intervals and the second portions 24y of the isolation region 24 are repeatedly arranged in the Y-direction at the predetermined intervals. However, the present technology is not limited to the lattice planar pattern with the intersection eliminated structure illustrated in FIG. 4 of the above-described first embodiment. For example, the present technology is also applicable to a lattice planar pattern with an intersection eliminated structure in which the second portions 24y of the isolation region 24 continuously extend in the Y-direction as illustrated in FIG. 10.

In addition, although illustration is omitted, the present technology is also applicable to a lattice planar pattern with an intersection eliminated structure in which, inversely to the lattice planar pattern with the intersection eliminated structure illustrated in FIG. 10, the first portions 24x of the isolation region 24 continuously extend in the X-direction.

It should be noted that the above-described first embodiment and the modification examples of the first embodiment employ an expression as the isolation region 24 including the first portions 24x and the second portions 24y, however, expressing the first portions 24x as the first isolation regions 24x and expressing the second portions 24y as the second isolation regions 24y are also, of course, acceptable.

### Second Embodiment

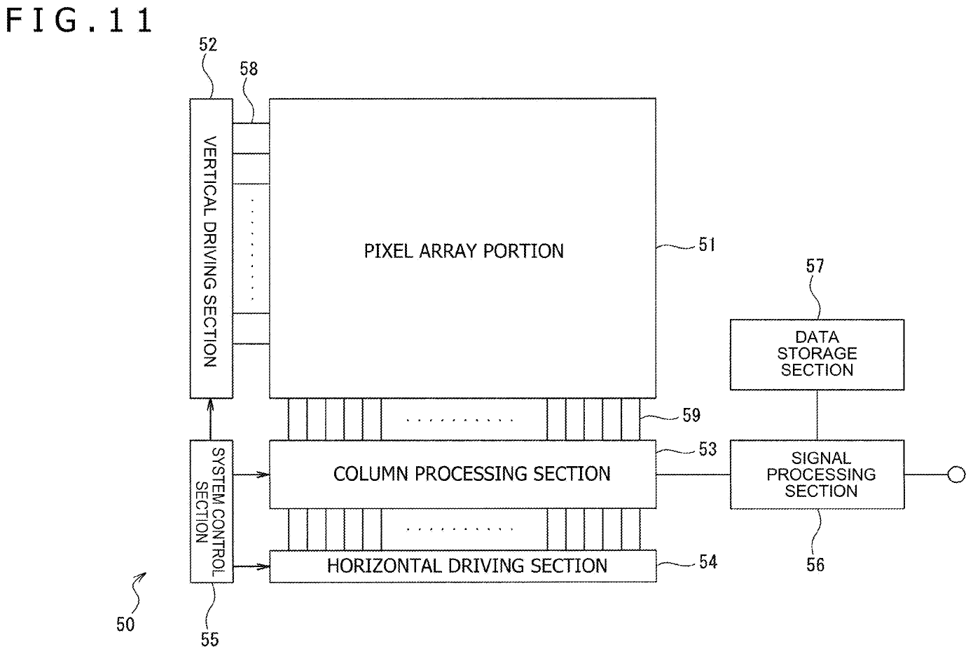

The present technology is applicable to all light detection devices including even a ranging sensor and the like in addition to the above-described solid-state imaging device as an image sensor, the ranging sensor being referred to as a ToF (Time of Flight) sensor and measuring measuring a distance. The ranging sensor is a sensor that outputs irradiation light toward an object, detects the irradiation light, or reflected light, reflected back by the object, and calculates a distance to the object on the basis of a time to flight elapsed from the output of the irradiation light to the reception of the reflected light. The structure of the above-described isolation region is usable as a structure of an isolation region of the ranging sensor. Description will be made below on an example where the present technology (the technology according to the present disclosure) is applied to a back-illuminated CAPD sensor, or ranging sensor, with reference to FIG. 11 to FIG. 13.

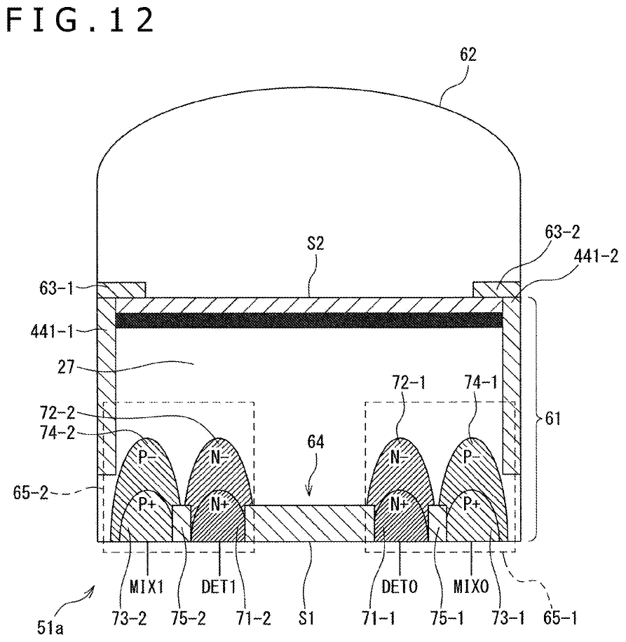

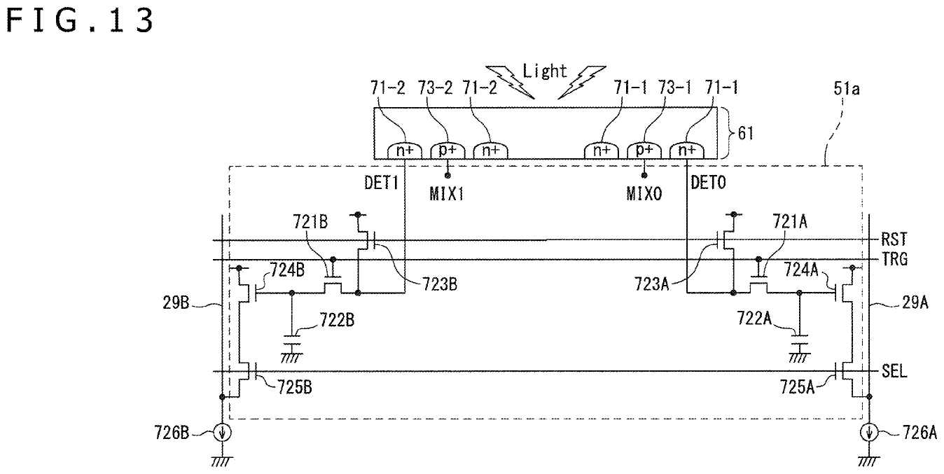

FIG. 11 is a block diagram illustrating a configuration example of a ranging sensor according to the second embodiment. FIG. 12 is a schematic cross-sectional view of a relevant part illustrating a configuration example of a pixel mounted in the ranging sensor according to the second embodiment. FIG. 13 is a diagram illustrating an equivalent circuit of the pixel mounted in the ranging sensor according to the second embodiment.

### Overall Configuration of Ranging Sensor

A ranging sensor 50 illustrated in FIG. 11, which is a back-illuminated CAPD sensor, is provided in an electronic apparatus having a ranging function.

As illustrated in FIG. 11, the ranging sensor 50 includes a pixel array portion 51 formed on a non-illustrated semiconductor substrate and a peripheral circuit section integrated on the same semiconductor substrate as the pixel array portion 51. The peripheral circuit section includes, for example, a vertical driving section 52, a column processing section 53, a horizontal driving section 54, and a system control section 55.

The ranging sensor 50 further includes a signal processing section 56 and a data storage section 57. It should be noted that the signal processing section 56 and the data storage section 57 may be mounted on the same substrate as the ranging sensor 50 or may be disposed on a substrate different from that of the ranging sensor 50.

The pixel array portion 51 includes unit pixels (hereinafter, also referred to simply as “pixels”) that generate charges depending on amounts of received light and output signals depending on the charges, the unit pixels being arranged in a row direction and a column direction, that is, two-dimensionally arranged in rows and columns. That is, the pixel array portion 51 includes multiple pixels that photoelectrically convert incoming light and output signals depending on the resulting charges.

Here, the row direction refers to an arrangement direction of the pixels in a pixel row (i.e., a horizontal direction) and the column direction refers to an arrangement direction of the pixels in a pixel column (i.e., a vertical direction). That is, the row direction is a crosswise direction in the figure and the column direction is a lengthwise direction in the figure.

In the pixel array portion 51, a pixel drive line 58 is wired along the row direction for each pixel row and two vertical signal lines 59 are wired along the column direction for each pixel column with respect to the pixel arrangement in rows and columns. For example, the pixel drive line 58 sends a drive signal for driving for reading a signal from a pixel. It should be noted that although FIG. 11 illustrates that the pixel drive line 58 is one wiring line, the number of lines is not limited to one. An end of the pixel drive line 58 is connected to an output end corresponding to each row in the vertical driving section 52.

The vertical driving section 52, which includes a shift resistor, an address decoder, and the like, drives the individual pixels of the pixel array portion 51 all together at the same time or on a pixel-by-pixel basis or the like. That is, the vertical driving section 52 serves as a driving section that controls operations of the individual pixels of the pixel array portion 51 along with the system control section 55 that controls the vertical driving section 52.

It should be noted that, as for indirect ToF ranging, the number of elements (CAPD elements) connected to one control line and that are to be driven at high speed has an influence on controllability of the high-speed driving and driving accuracy. Solid-state imaging elements (ranging sensors) usable for indirect ToF are often in a form of a pixel array elongated in the horizontal direction. Accordingly, in such a form, for control lines for the elements that are to be driven at high speed, the vertical signal lines 59 or any other control lines elongated in the vertical direction may be used. In this case, for example, multiple pixels arranged in the vertical direction are connected to the vertical signal lines 59 or any other control lines elongated in the vertical direction and a driving section provided separately from the vertical driving section 52, the horizontal driving section 54, and the like causes the pixels, that is, the CAPD sensors to be driven through the vertical signal lines 59 or any other control lines.

The signals outputted from the individual pixels in pixel rows according to a driving control by the vertical driving section 52 are inputted to the column processing section 53 through the vertical signal lines 59. The column processing section 53 applies predetermined signal processing to the signals outputted from the individual pixels through the vertical signal lines 59 and temporarily holds the signal-processed pixel signals.

Specifically, the column processing section 53 performs, as the signal processing, a denoising process, an AD (Analog to Digital) conversion process, and the like.

The horizontal driving section 54, which includes a shift resistor, an address decoder, and the like, selects a unit circuit corresponding to a pixel column in the column processing section 53 in order. The selection scanning by the horizontal driving section 54 causes the pixel signals signal-processed by the column processing section 53 to be outputted in order on a unit-circuit-by-unit-circuit basis.

The system control section 55, which includes a timing generator that generates a variety of timing signals, and the like, controls driving of the vertical driving section 52, the column processing section 53, the horizontal driving section 54, and the like on the basis of the variety of timing signals generated by the timing generator.

The signal processing section 56, which has at least an arithmetic processing function, performs a variety of signal processing such as arithmetic processing on the basis of the pixel signals outputted from the column processing section 53. For the signal processing in the signal processing section 56, the data storage section 57 temporarily stores data necessary for the processing.

### Configuration of Pixels

Next, description will be made on a configuration example of the pixels provided in the pixel array portion 51. Pixels 51a provided in the pixel array portion 51 are configured, for example, as illustrated in FIG. 12.

FIG. 12 illustrates a cross section of one of the pixels 51a provided in the pixel array portion 51. The pixel 51a receives externally incoming light, especially, infrared light, performs photoelectric conversion, and outputs a signal depending on the resulting charge.

The pixel 51a includes, for example, a silicon substrate, namely, substrate 61 (semiconductor layer), and an on-chip lens 62 formed on the substrate 61, the substrate 61 being in a form of a p-type semiconductor substrate having a p-type semiconductor region.

For example, the substrate 61 is caused to have a lengthwise directional thickness, that is, a thickness in a direction vertical to a surface of the substrate 61, of 20 μm or less in the figure. It should be noted that the thickness of the substrate 61 may, of course, be 20 μm or more and it is only sufficient if the thickness is determined according to an aimed performance or the like of a solid-state imaging element 11.

In addition, the substrate 61 is a high-resistance P-Epi substrate with a substrate concentration of, for example, 1E+13 order or less, or the like and a resistance (a resistivity) of the substrate 61 is caused to be, for example, 500 [Ω cm] or more.

Here, examples of a relation between the substrate concentration and the resistance of the substrate 61 include a resistance of 2000 [Ω cm] at a substrate concentration of 6.48E+12 [cm3], a resistance of 1000 [Ω cm] at a substrate concentration of 1.30E+13 [cm3], a resistance of 500 [Ω cm] at a substrate concentration of 2.59E+13 [cm3], and a resistance of 100 [Ω cm] at a substrate concentration of 1.30E+14 [cm3].

The on-chip lens 62 is formed on an upper surface of the substrate 61 in the figure, that is, a surface on a side of the substrate 61 where externally incoming light is to enter (hereinafter, also referred to as entrance surface), the on-chip lens 62 collecting the externally incoming light and causing the light to enter the inside of the substrate 61.

Further, in the pixel 51a, an interpixel light shield 63-1 and an interpixel light shield 63-2 for preventing color mixing between adjacent ones of the pixels are formed in an end portion of the pixel 51a on the entrance surface of the substrate 61.

In this example, while the external light is to enter the inside of the substrate 61 through the on-chip lens 62, the externally incoming light is prevented from passing through a part of the on-chip lens 62 or the substrate 61 to enter a region of another pixel provided adjacent to the pixel 51a in the substrate 61. That is, the light externally entering the on-chip lens 62 and directed toward the inside of another pixel adjacent to the pixel 51a is blocked by the interpixel light shield 63-1 or the interpixel light shield 63-2 so as not to enter the inside of the other adjacent pixel. Hereinafter, the interpixel light shield 63-1 and the interpixel light shield 63-2 are also referred to simply as interpixel light shield 63 unless they need to be particularly distinguished.

Since the ranging sensor 50 is a back-illuminated CAPD sensor, the entrance surface of the substrate 61 is a generally-called back surface and no wiring layer including a wiring line and the like is formed on the back surface. In addition, a wiring layer is formed on a portion of the opposite surface of the substrate 61 to the entrance surface by stacking. In the wiring layer, a wiring line for driving a transistor and the like formed in the pixel 51a, a wiring line for reading a signal from the pixel 51a, and the like are formed.

An oxide film 64 and a signal extraction section 65-1 and a signal extraction section 65-2 called Taps are formed on the opposite surface side to the entrance surface within the substrate 61, that is, an internal portion of a lower surface in the figure.

In this example, the oxide film 64 is formed at a central portion of the pixel 51 near the opposite surface of the substrate 61 to the entrance surface and the signal extraction section 65-1 and the signal extraction section 65-2 are formed at respective opposite ends of the oxide film 64.

Here, the signal extraction section 65-1 has an N+ semiconductor region 71-1 that is an N-type semiconductor region, an N− semiconductor region 72-1 that is lower in concentration of donor impurity than the N+ semiconductor region 71-1, a P+ semiconductor region 73-1 that is a P-type semiconductor region, and a P− semiconductor region 74-1 that is lower in acceptor impurity concentration than the P+ semiconductor region 73-1. Here, examples of the donor impurity include elements belonging to the fifth group of the periodic table of elements, such as phosphorus (P) and arsenic (As), relative to Si and examples of the acceptor impurity include elements belonging to the third group of the periodic table of elements, such as boron (B), relative to Si. An element that is the donor impurity is referred to as a donor impurity and an element that is the acceptor impurity is referred to as an acceptor element.

That is, the N+ semiconductor region 71-1 is formed in an in-plane portion of the opposite surface of the substrate 61 to the entrance surface at a position adjacent to, in the figure, a right side of the oxide film 64. In addition, the N− semiconductor region 72-1 is formed on, in the figure, an upper side of the N+ semiconductor region 71-1 to cover (surround) the N+ semiconductor region 71-1.

Further, the P+ semiconductor region 73-1 is formed in an in-plane portion of the opposite surface of the substrate 61 to the entrance surface at a position adjacent to, in the figure, a right side of the N+ semiconductor region 71-1. In addition, the P− semiconductor region 74-1 is formed on, in the figure, an upper side of the P+ semiconductor region 73-1 to cover (surround) the P+ semiconductor region 73-1.

It should be noted that although illustration is omitted here, in more detail, the N+ semiconductor region 71-1 and the N− semiconductor region 72-1 are formed around the P+ semiconductor region 73-1 and the P− semiconductor region 74-1 to circumferentially surround the P+ semiconductor region 73-1 and the P− semiconductor region 74-1, respectively, when the substrate 61 is viewed from a direction vertical to the surface of the substrate 61.

Likewise, the signal extraction section 65-2 includes an N+ semiconductor region 71-2 that is an N-type semiconductor region, an N− semiconductor region 72-2 that is lower in concentration of donor impurity than the N+ semiconductor region 71-2, a P+ semiconductor region 73-2 that is a P-type semiconductor region, and a P− semiconductor region 74-2 that is lower in acceptor impurity concentration than the P+ semiconductor region 73-2.

That is, the N+ semiconductor region 71-2 is formed in an in-plane portion of the opposite surface of the substrate 61 to the entrance surface at a position adjacent to, in the figure, a left side of the oxide film 64. In addition, the N− semiconductor region 72-2 is formed on, in the figure, an upper side of the N+ semiconductor region 71-2 to cover (surround) the N+ semiconductor region 71-2.

Further, the P+ semiconductor region 73-2 is formed in an in-plane portion of the opposite surface of the substrate 61 to the entrance surface at a position adjacent to, in the figure, a left side of the N+ semiconductor region 71-2. In addition, the P− semiconductor region 74-2 is formed on, in the figure, an upper side of the P+ semiconductor region 73-2 to cover (surround) the P+ semiconductor region 73-2.

It should be noted that although illustration is omitted here, in more detail, the N+ semiconductor region 71-2 and the N− semiconductor region 72-2 are formed around the P+ semiconductor region 73-2 and the P− semiconductor region 74-2 to circumferentially surround the P+ semiconductor region 73-2 and the P− semiconductor region 74-2, respectively, when the substrate 61 is viewed from a direction vertical to the surface of the substrate 61.

Hereinafter, the signal extraction section 65-1 and the signal extraction section 65-2 are also referred to simply as signal extraction section 65 unless they need to be particularly distinguished.

In addition, hereinafter, the N+ semiconductor region 71-1 and the N+ semiconductor region 71-2 are also referred to simply as N+ semiconductor region 71 unless they need to be particularly distinguished, and the N− semiconductor region 72-1 and the N− semiconductor region 72-2 are also referred to simply as the N− semiconductor region 72 unless they need to be particularly distinguished.

Further, hereinafter, the P+ semiconductor region 73-1 and the P+ semiconductor region 73-2 are also referred to simply as P+ semiconductor region 73 unless they need to be particularly distinguished, and the P− semiconductor region 74-1 and the P− semiconductor region 74-2 are also referred to simply as P− semiconductor region 74 unless they need to be particularly distinguished.

In addition, in the substrate 61, an isolation portion 75-1 including an oxide film or the like is formed between the N+ semiconductor region 71-1 and the P+ semiconductor region 73-1 so as to isolate these regions. Likewise, an isolation portion 75-2 including an oxide film or the like is formed also between the N+ semiconductor region 71-2 and the P+ semiconductor region 73-2 so as to isolate these regions. Hereinafter, the isolation portion 75-1 and the isolation portion 75-2 are also referred to simply as isolation portion 75 unless they need to be particularly distinguished.

The N+ semiconductor region 71 provided in the substrate 61 functions as a charge detection section for detecting the amount of light externally entering the pixel 51a, that is, detecting the amount of a signal carrier generated by the photoelectric conversion through the substrate 61. It should be noted that a region also including the N− semiconductor region 72 with a lower donor impurity concentration in addition to the N+ semiconductor region 71 may be considered as the charge detection section. In addition, the P+ semiconductor region 73 functions as a voltage application section for injecting majority carrier current into the substrate 61, that is, for applying voltage directly to the substrate 61 to generate an electric field in the substrate 61. It should be noted that a region also including the P− semiconductor region 74 with a lower acceptor impurity concentration in addition to the P+ semiconductor region 73 may be considered as the voltage application section.

In the pixel 51a, the N+ semiconductor region 71-1 is directly connected to a non-illustrated floating diffusion region, or FD (Floating Diffusion) portion (hereinafter, also referred to particularly as FD section A) and, further, the FD section A is connected to the vertical signal line 59 through a non-illustrated amplification transistor or the like.

Likewise, the N+ semiconductor region 71-2 is connected directly to another FD section (hereinafter, also referred to particularly as FD section B) different from the FD section A and, further, the FD section B is connected to the vertical signal line 59 through a non-illustrated amplification transistor or the like. Here, the FD section A and the FD section B are connected to the respective different vertical signal lines 59.

For example, in a case where a distance to a target is to be measured by indirect ToF, infrared light is outputted from an imaging device provided with the solid-state imaging element 11 toward the target. Then, when the infrared light is reflected by the target to return as reflected light to the imaging device, the substrate 61 of the solid-state imaging element 11 receives the incoming reflected light (infrared light) and performs photoelectric conversion.

At this time, the vertical driving section 52 drives the pixel 51a to distribute signals depending on charges obtained by the photoelectric conversion between the FD section A and the FD section B. It should be noted that, instead of being performed by the vertical driving section 52 as described above, driving of the pixel 51a may be performed by a separate driving section, the horizontal driving section 54, or the like through the vertical signal line 59 or another control line elongated in the vertical direction.

For example, the vertical driving section 52 applies voltage to the two P+ semiconductor regions 73 through a contact or the like at some timing. Specifically, for example, the vertical driving section 52 applies a voltage of 1.5 V to the P+ semiconductor region 73-1 and applies a voltage of 0 V to the P+ semiconductor region 73-2.

Subsequently, an electric field is generated between the two P+ semiconductor regions 73 in the substrate 61 and current flows from the P+ semiconductor region 73-1 to the P+ semiconductor region 73-2. In this case, holes in the substrate 61 move in a direction toward the P+ semiconductor region 73-2 and electrons move in a direction toward the P+ semiconductor region 73-1.

Thus, when external infrared light (reflected light) enters the inside of the substrate 61 through the on-chip lens 62 in such a state and the infrared light is photoelectrically converted to pairs of electrons and holes in the substrate 61, the electric field between the P+ semiconductor regions 73 causes the obtained electrons to be guided in the direction toward the P+ semiconductor region 73-1 to move into the N+ semiconductor region 71-1.

In this case, the electrons generated by the photoelectric conversion are used as a signal carrier for detecting the amount of the infrared light entering the pixel 51a, that is, a signal depending on the received amount of the infrared light.

This causes a charge depending on the electrons moving into the N+ semiconductor region 71-1 to be accumulated in the N+ semiconductor region 71-1 and the charge is detected by the column processing section 53 through the FD section A, the amplification transistor, a vertical signal line 29, and the like.

That is, the accumulated charge in the N+ semiconductor region 71-1 is transferred to the FD section A directly connected to the N+ semiconductor region 71-1 and a signal depending on the charge transferred to the FD section A is read by the column processing section 53 through the amplification transistor and the vertical signal line 59. The read signal is then subjected to a process such as an AD conversion process in the column processing section 53 and the resulting pixel signal is supplied to the signal processing section 26.

The pixel signal is a signal indicating a charge amount depending on the electrons detected by the N+ semiconductor region 71-1, that is, the amount of the charge accumulated in the FD section A. In other words, the pixel signal can also be referred to as a signal indicating the amount of the infrared light received by the pixel 51a.

It should be noted that, at this time, the pixel signal depending on the electrons detected in the N+ semiconductor region 71-2 may also be usable for ranging, if necessary, as in the case of the N+ semiconductor region 71-1.

In addition, at the next timing, voltage is applied to the two P+ semiconductor regions 73 by the vertical driving section 22 through the contact and the like to cause an electric field in the opposite direction to that of the electric field generated so far in the substrate 61 to be generated. Specifically, for example, a voltage of 1.5 V is applied to the P+ semiconductor region 73-2 and a voltage of 0 V is applied to the P+ semiconductor region 73-1.

This causes an electric field to be generated between the two P+ semiconductor regions 73 in the substrate 61, causing current to flow from the P+ semiconductor region 73-2 to the P+ semiconductor region 73-1.

When external infrared light (reflected light) enters the inside of the substrate 61 through the on-chip lens 62 in such a state and the infrared light is photoelectrically converted to pairs of electrons and holes in the substrate 61, the electric field between the P+ semiconductor regions 73 causes the obtained electrons to be guided in the direction toward the P+ semiconductor region 73-2 to move into the N+ semiconductor region 71-2.

This causes a charge depending on the electrons moving into the N+ semiconductor region 71-2 to be accumulated in the N+ semiconductor region 71-2 and the charge is detected by the column processing section 53 through the FD section B, the amplification transistor, the vertical signal line 29, or the like.

That is, the accumulated charge in the N+ semiconductor region 71-2 is transferred to the FD section B directly connected to the N+ semiconductor region 71-2 and a signal depending on the charge transferred to the FD section B is read by the column processing section 53 through the amplification transistor and the vertical signal line 59. The read signal is then subjected to a process such as an AD conversion process in the column processing section 53 and the resulting pixel signal is supplied to the signal processing section 56.

It should be noted that, at this time, the pixel signal depending on the electrons detected in the N+ semiconductor region 71-1 may also be usable for ranging, if necessary, as in the case of the N+ semiconductor region 71-2.

In such a manner, in response to pixel signals being obtained by photoelectric conversion during respective different periods of time in the same pixel 51a, the signal processing section 56 calculates distance information indicating a distance to a target on the basis of the pixel signals.

A method in which signal carriers are distributed to the respective different N+ semiconductor regions 71 and distance information is calculated on the basis of signals depending on the signal carriers is called indirect ToF.

It should be noted that description is made here on the example where the vertical driving section 52 performs a control of application of voltage to the P+ semiconductor regions 73, however, a driving section (a block) that functions as a voltage application control section that performs a control of application of voltage to the P+ semiconductor regions 73 may be provided in the ranging sensor 50 separately from the vertical driving section 52 as described above.

In the configuration of the pixel 51a illustrated in FIG. 12, an isolation region 441-1 and an isolation region 441-2 are provided in the substrate 61. The substrate 61 has a first surface S1 and a second surface S2 located on opposite sides to each other.

In the pixel 51a illustrated in FIG. 12, the isolation region 441-1 and the isolation region 441-2 penetrating at least a part of the substrate 61 are formed at boundary portions in the substrate 61 between the pixel 51a and other pixels adjacent to the pixel 51a, that is, at right and left end portions of the pixel 51a in the figure, the isolation region 441-1 and the isolation region 441-2 including a light-shielding film or the like. It should be noted that the isolation region 441-1 and the isolation region 441-2 are hereinafter also referred to simply as isolation region 441 unless they need to be particularly distinguished.

For example, for the formation of the isolation region 441, a long groove (trench) is formed in a downward direction (a direction vertical to the surface of the substrate 61) from a side of a light entrance surface, that is, an upper surface in the figure, of the substrate 61) and a light-shielding film is formed in the groove by embedding to provide the isolation region 441. The isolation region 441 functions as a pixel isolation region that blocks infrared light entering the inside of the substrate 61 through the entrance surface and traveling toward another pixel adjacent to the pixel 51a.

The formation of such an embedded isolation region 441 makes it possible to improve an isolation performance for infrared light between pixels to reduce the occurrence of color mixing.

The substrate 61 includes multiple photoelectric conversion regions 27 defined by the isolation region 441. The photoelectric conversion regions 27 are provided in the pixels 51a on a one-by-one basis and the photoelectric conversion region of each of the pixels 51a includes the above-described signal extraction section 65-1 including the N+ semiconductor region 71-1, the P+ semiconductor region 73-1, and the like and the signal extraction section 65-2 including the N+ semiconductor region 71-2, the P+ semiconductor region 73-2, and the like.

The isolation region 441 is formed in a lattice planar pattern as the isolation region 24 of the above-described first embodiment. That is, as described with reference to FIG. 5 to FIG. 8 of the above-described first embodiment, the isolation region 441 of the second embodiment is also in a lattice planar pattern in which the first portions 24x extending in the X-direction and the second portions 24y extending in the Y-direction are spaced from each other in plan view with intersections between the first portions 24x and the second portions 24y being eliminated. Additionally, in the first planar pattern 26a, the semiconductor layer 20 (the substrate 61) between the first portions 24x and the second portions 24y of the isolation region 24 (the isolation region 441) has the first side portion 20y₁ on the side of the first portion 24x and the second side portion 20y₂ on the side of the second portion 24y, which are different in shape as illustrated in FIG. 6. In addition, in the second planar pattern 26b, the semiconductor layer 20 between the second portions 24y and the first portions 24x of the isolation region 24 has different planar shapes between the first side portion 20x₁ on the side of the second portion 24y and the second side portion 20x₂ on the side of the first portion 24x as illustrated in FIG. 8. In the second embodiment, the first side portions 20y₁ and 20x₁ are also in a planar shape and the second side portions 20y₂ and 20x₂ are in a recessed curved shape.

The ranging sensor 50 according to the second embodiment also produces an effect similar to that of the solid-state imaging device 1A according to the above-described first embodiment.

It should be noted that the isolation region 441 of the second embodiment is configured to extend from the side of the second surface S2 toward the side of the first surface S1 of the substrate 61 and is spaced from the first surface S1 as the above-described isolation region 24A of the modification example 1-1 of the first embodiment. A depth of the isolation region 441 in this case is smaller than the thickness of the substrate 61.

### Configuration of Equivalent Circuit of Pixel

FIG. 13 is a diagram illustrating an equivalent circuit of the pixel mounted in the ranging sensor according to the second embodiment. The pixel 51a includes, for the signal extraction section 65-1 including the N+ semiconductor region 71-1, the P+ semiconductor region 73-1, and the like, a transfer transistor 721A, an FD 722A, a reset transistor 723A, an amplification transistor 724A, and a selection transistor 725A.

In addition, the pixel 51a includes, for the signal extraction section 65-2 including the N+ semiconductor region 71-2, the P+ semiconductor region 73-2, and the like, a transfer transistor 721B, an FD 722B, a reset transistor 723B, an amplification transistor 724B, and a selection transistor 725B.

The vertical driving section 22 applies a predetermined voltage MIX0 (a first voltage) to the P+ semiconductor region 73-1 and applies a predetermined voltage MIX1 (a second voltage) to the P+ semiconductor region 73-2. In the above-described example, one of the voltages MIX0 and MIX1 is 1.5 V and the other is 0 V. The P+ semiconductor regions 73-1 and 73-2 are voltage application sections to which the first voltage and the second voltage are to be applied.

The N+ semiconductor regions 71-1 and 71-2 are charge detection sections that detect a charge generated by photoelectrically converting light entering the substrate 61 and accumulate the charge.

The transfer transistor 721A gets into a current-through state in response to a drive signal TRG supplied to a gate electrode getting into an active state, thus transferring the charge accumulated in the N+ semiconductor region 71-1 to the FD 722A. The transfer transistor 721B gets into a current-through state in response to the drive signal TRG supplied to the gate electrode getting into the active state, thus transferring the charge accumulated in the N+ semiconductor region 71-2 to the FD 722B.

The FD 722A temporarily holds the charge supplied from the N+ semiconductor region 71-1. The FD 722B temporarily holds the charge supplied from the N+ semiconductor region 71-2. The FD 722A corresponds to the FD section A described with reference to FIG. 2 and the FD 722B corresponds to the FD section B.

The reset transistor 723A gets into a current-through state in response to a drive signal RST supplied to the gate electrode getting into an active state, thus resetting a potential of the FD 722A to a predetermined level (a reset voltage VDD). The reset transistor 723B gets into a current-through state in response to a drive signal RST supplied to a gate electrode getting into the active state, thus resetting a potential of the FD 722B to the predetermined level (the reset voltage VDD). It should be noted that when the reset transistors 723A and 723B are in the active state, the transfer transistors 721A and 721B are simultaneously in the active state.

The amplification transistor 724A is connected to a vertical signal line 29A at a source electrode through the selection transistor 725A, thus forming a source follower circuit with a load MOS of a constant current source circuit section 726A connected to one end of the vertical signal line 29A. The amplification transistor 724B is connected to a vertical signal line 29B at a source electrode through the selection transistor 725B, thus forming a source follower circuit with a load MOS of a constant current source circuit section 726B connected to one end of the vertical signal line 29B.

The selection transistor 725A is connected between the source electrode of the amplification transistor 724A and the vertical signal line 29A. The selection transistor 725A gets into a current-through state in response to a selection signal SEL supplied to a gate electrode getting into an active state, thus outputting the pixel signal outputted from the amplification transistor 724A to the vertical signal line 29A.

The selection transistor 725B is connected between the source electrode of the amplification transistor 724A and the vertical signal line 29B. The selection transistor 725B gets into a current-through state in response to a selection signal SEL supplied to a gate electrode getting into an active state, thus outputting the pixel signal outputted from the amplification transistor 724B to the vertical signal line 29B.

The transfer transistors 721A and 721B, the reset transistors 723A and 723B, the amplification transistors 724A and 724B, and the selection transistors 725A and 725B of the pixel 51a are controlled by, for example, the vertical driving section 52.

### Modification Example of Second Embodiment

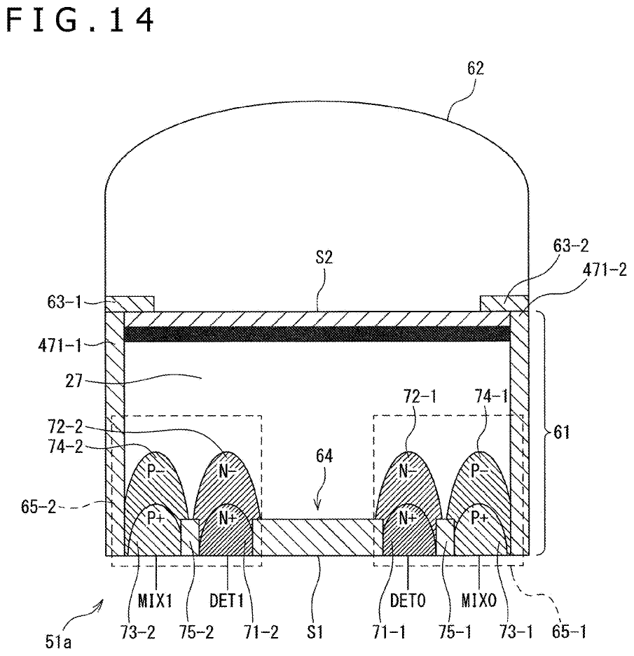

In the above-described second embodiment, description is made on the isolation region 441 extending from the side of the second surface S2 toward the side of the first surface S1 of the substrate 61 and spaced from the first surface S1. The present technology is not limited to the isolation region 441 illustrated in FIG. 12 of the above-described second embodiment. For example, the present technology is also applicable to an isolation region 471-1 and an isolation region 471-2 penetrating across the second surface S2 and the first surface S1 of the substrate 61 as illustrated in FIG. 14.

### Third Embodiment

According to an existing technique for a solid-state imaging device, multiple photoelectric conversion elements are embedded below one on-chip lens to achieve pupil division and the technique is used for, for example, a built-in camera for electronic apparatuses such as a single-lens reflex camera and a smartphone. In addition, according to a known technique for a solid-state imaging device, signal charges photoelectrically converted by multiple photoelectric conversion elements located under one on-chip lens are each read as an independent signal to detect a phase difference. In the third embodiment, description will be made on an example where the present technology is provided to a solid-state imaging device having a photoelectric conversion region including two photoelectric conversion sections.

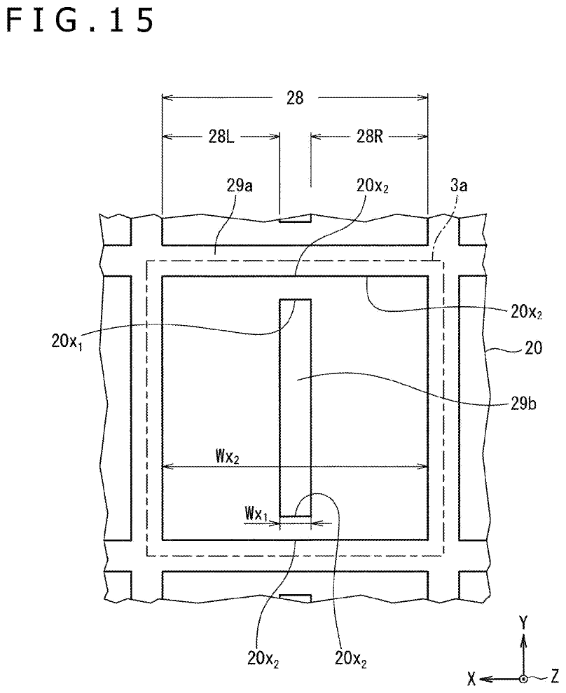

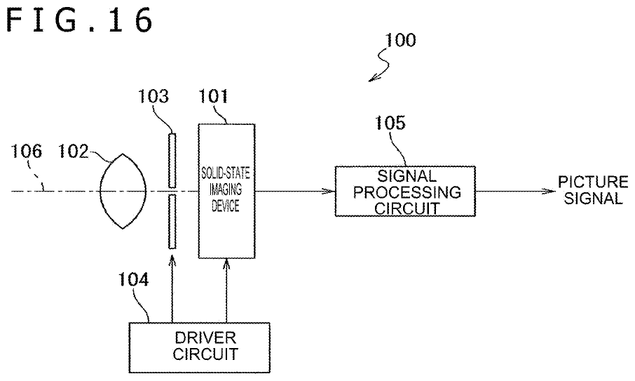

The solid-state imaging device according to the third embodiment includes a pixel 3a illustrated in FIG. 15.

The pixel 3a has a photoelectric conversion region 28 provided in a semiconductor layer 20. The photoelectric conversion region 28 is defined by a first isolation region (a pixel isolation region) 29a provided in the semiconductor layer 20.

The photoelectric conversion region 28 includes a first photoelectric conversion section 28L and the second photoelectric conversion section 28R. A second isolation region (an in-pixel isolation region) 28b is provided between the first photoelectric conversion section 28L and the second photoelectric conversion section 28R. The first photoelectric conversion section 28L and the second photoelectric conversion section 28R are each provided with, for example, a photodiode as a photoelectric conversion element.

The first isolation region 29a and the second isolation region 29b each include a groove extending from a side of a second surface S2 of the semiconductor layer 20 toward a side of an opposite first surface S1 and an insulation film embedded in the groove as the isolation region 24 illustrated in FIG. 3 of the above-described first embodiment.

As illustrated in FIG. 15, the first isolation region 29a is in a rectangular annular planar pattern in plan view. The second isolation region 29b extends in the Y-direction in plan view within the first isolation region 29a. The second isolation region 29b is spaced from the first isolation region 29a and an end of the second isolation region 29b is opposed to the first isolation region 29a with the semiconductor layer 20 in between in plan view.

The semiconductor layer 20 between the first isolation region 29a and the second isolation region 29b includes a first side portion 20x₁ on a side of the second isolation region 29b and a second side portion 20x₂ on a side of the first isolation region 29a. The first side portion 20x₁ and the second side portion 20x₂ are similar in configuration to the first side portion 20x₁ and the second side portion 20x₂ of the above-described first embodiment. That is, a width Wx₂ of the second side portion 20x₂ is wider than an X-directional width Wx₁ of the first side portion 20x₁ in plan view, the width Wx₂ being the same in direction as the width Wx₁. Additionally, the first side portion 20x₁ is formed in a planar shape and the second side portion 20x₂ is formed in a curved shape.

The solid-state imaging device according to the third embodiment also produces an effect similar to that of the above-described first embodiment.

### Fourth Embodiment

### Example of Application to Electronic Apparatus

The present technology (the technology according to the present disclosure) is applicable to any of various electronic apparatuses, for example, an imaging device such as a digital still camera or a digital video camera, a mobile phone having an imaging function, or any other apparatus having an imaging function.

FIG. 16 is a diagram illustrating a schematic configuration of an electronic apparatus (for example, a camera) according to a fourth embodiment of the present technology.

As illustrated in FIG. 16, an electronic apparatus 100 includes a solid-state imaging device 101, an optical lens 102, a shutter device 103, a driver circuit 104, and a signal processing circuit 105. The electronic apparatus 100 exemplifies a case where an electronic apparatus (for example, a camera) includes, as the solid-state imaging device 101, a solid-state imaging device and a ranging sensor according to of the present technology.

The optical lens 102 causes image light (incoming light 106) from a subject to be formed as an image on an imaging plane of the solid-state imaging device 101. This causes a signal charge to be accumulated in the solid-state imaging device 101 during a predetermined period of time. The shutter device 103 controls a light-irradiation period and a light-shielding period for the solid-state imaging device 101. The driver circuit 104 supplies a drive signal that controls a transfer operation of the solid-state imaging device 101 and a shutter operation of the shutter device 103. In response to the drive signal (a timing signal) supplied from the driver circuit 104, the solid-state imaging device 101 performs signal transfer. The signal processing circuit 105 applies a variety of signal processing to a signal (a pixel signal) outputted from the solid-state imaging device 101. A signal-processed picture signal is stored in a storage medium such as a memory or outputted to a monitor.

By virtue of such a configuration, a light-reflection reduction section in the solid-state imaging device 101 reduces light reflection on a light-shielding film and an insulation film being in contact with an air layer in the electronic apparatus 100 of the fourth embodiment, which makes it possible to reduce flare to improve an image quality.

It should be noted that the electronic apparatus 100 for which the solid-state imaging device of the above-described embodiment is usable is not limited to a camera and the solid-state imaging device is also usable for any other electronic apparatus. For example, the solid-state imaging device may be used as an imaging device such as a camera module for mobile equipment such as a mobile phone and a tablet terminal.

### Fifth Embodiment

### Example of Application to Electronic Apparatus

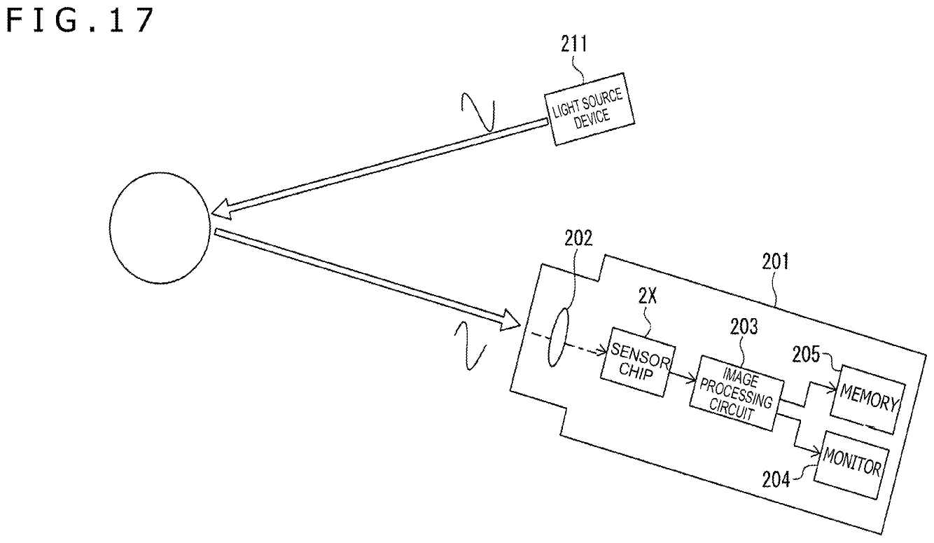

As illustrated in FIG. 17, a distance image apparatus 201 as an electronic apparatus includes an optical system 202, a sensor chip 2X, an image processing circuit 203, a monitor 204, and a memory 205. The distance image apparatus 201 is able to acquire a distance image depending on a distance to a subject by receiving light (modulated light or pulsed light) projected toward the subject from a light source device 211 and reflected by a surface of the subject.

The optical system 202, which includes one or multiple lenses, guides the image light (incoming light) from the subject to the sensor chip 2X and causes the image light to be formed as an image on a light-receiving surface (a sensor section) of the sensor chip 2X.

A sensor chip (a semiconductor chip) equipped with the solid-state imaging device or the ranging of the above-described embodiment is used as the sensor chip 2X and a distance signal is supplied to the image processing circuit 203, the distance signal indicating a distance determined from a light-receiving signal (APD OUT) outputted from the sensor chip 2X.

The image processing circuit 203 performs image processing that constructs a distance image on the basis of the distance signal supplied from the sensor chip 2X and the distance image (image data) obtained through the image processing is supplied to the monitor 204 to be displayed or supplied to the memory 205 to be stored (recorded).

In the distance image apparatus 201 with such a configuration, a use of the sensor chip equipped with the solid-state imaging device or the ranging sensor of the above-described embodiment makes it possible to compute a distance to a subject only on the basis of a light-receiving signal from a highly stabile pixel to generate a highly accurate distance image. That is, the distance image apparatus 201 is allowed to acquire a more accurate distance image.

### Examples of Use of Image Sensor

The sensor chip equipped with the solid-state imaging device or the ranging sensor of the above-described embodiment is usable in a variety of cases where, for example, light such as visible light, infrared light, ultraviolet light, or X-ray is to be sensed as follows.
devices that photograph an image to be provided for viewing purposes, such as a digital camera and mobile equipment with a camera function
devices provided for traffic purposes, such as an in-vehicle sensor that photographs a forward side, a rear side, surroundings, vehicle interior, or the like of an automobile for the purpose of safety driving such as automatic stop or recognition of the condition of a driver, a surveillance camera that monitors a moving vehicle or a road, and a ranging sensor that performs ranging between vehicles or the like
devices provided in home electrical appliances, such as a television set, a refrigerator, and an air conditioner, for the purpose of photographing a gesture of a user to operate the appliances according to the gesture
devices provided for medical or healthcare purposes, such as an endoscope and a device that performs angiography by receiving infrared light
devices provided for security purposes, such as a surveillance camera for use in security and a camera for use in person recognition
devices provided for cosmetic purposes, such as a skin measurement instrument that photographs a skin and a microscope that photographs a scalp
devices for sports purposes, such as an action camera and a wearable camera for use in sports
devices provided for agricultural purposes, such as a camera for monitoring the state of a field or a crop

It should be noted that the configuration of the present technology may be as follows.

(1)

A light detection device including:
a semiconductor layer having a photoelectric conversion region defined by an isolation region including a groove, in which
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.
   (2)

The light detection device according to (1) above, in which the first side portion is in a planar shape and the second side portion is in a curved shape.

(3)

The light detection device according to (1) or (2) above, in which a width of the second side portion in a same direction as a width of the first side portion is wider than the width of the first side portion in plan view.

(4)

The light detection device according to any one of (1) to (3), in which the first portion is provided on each of width directional opposite sides of the second portion in plan view.

(5)

The light detection device according to any one of (1) to (4), in which
the first portion extends in a first direction in plan view, and
the second portion extends in a second direction orthogonal to the first direction in plan view.
   (6)

The light detection device according to any one of (1) to (5), in which the isolation region extends from, out of a first surface and a second surface of the semiconductor layer located on opposite sides to each other, a side of the second surface toward a side of the first surface.

(7)

The light detection device according to any one of (1) to (6), further including:
a multilayer wiring layer provided on a side of a light entrance surface of the semiconductor layer; and
a microlens provided on an opposite side of the multilayer wiring layer to a side of the semiconductor layer.
   (8)

A light detection device including:
a semiconductor layer having a photoelectric conversion region defined by an isolation region including a groove; and
two transfer transistors provided in the photoelectric conversion region, in which
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.
   (9)

An electronic apparatus including:
a light detection device;
an optical lens configured to cause image light from a subject to be formed as an image on an imaging plane of the light detection device; and
a signal processing circuit configured to apply signal processing to a signal outputted from the light detection device, in which
the light detection device includes a semiconductor layer having a photoelectric conversion region defined by an isolation region including a groove,
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.
   (10)

An electronic apparatus including:
a light detection device;
an optical lens configured to cause image light from a subject to be formed as an image on an imaging plane of the light detection device; and
a signal processing circuit configured to apply signal processing to a signal outputted from the light detection device, in which
the light detection device includes
   a semiconductor layer having a photoelectric conversion region defined by an isolation region including a groove, and
   two transfer transistors provided in the photoelectric conversion region,
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.

The scope of the present technology is by no means limited to the exemplary embodiments as illustrated and described and also includes all embodiments that produce effects equivalent to the object of the present technology. Further, the scope of the present technology is by no means limited to a combination of features of the invention defined by claims and may be defined by any desired combination of specific ones of all the disclosed individual features.

### Reference Signs List

1A: Solid-state imaging device
2: Semiconductor chip
2A: Pixel array portion
3B: Peripheral portion
2: Semiconductor chip
2A: Pixel array portion
2B: Peripheral portion
2C: Pad arrangement portion
3: Pixel
4: Vertical driver circuit
5: Column signal processing circuit
6: Horizontal driver circuit
7: Output circuit
8: Control circuit
10: Pixel driving wiring line
11: Vertical signal line
12: Horizontal signal line
13: Logic circuit
14: Bonding pad
20: Semiconductor layer
20x₁, 20y₁: First side portion
20x₂, 20y₂: Second side portion
21: p-type well region
22: Groove
23: Insulation film
24: Isolation region
24x: First portion
24y: Second portion
25x: X-directional isolation array
25y: Y-directional isolation array
26a: First pattern
26b: Second pattern
27 Photoelectric conversion region
28: Photoelectric conversion region
28L: First photoelectric conversion section
28R: Second photoelectric conversion section
29a: First isolation region
29b: Second isolation region
30: Multilayer wiring layer
31: Interlayer insulation film
32: Wiring line
34: Support substrate
36: Flattened film
37: Light-shielding film
38: Sticky film
40: Color filter layer
41: First color filter section for red (R)
42: Second color filter section for green (G)
43: Third color filter section for blue (B)
45: Microlens
50: Ranging sensor
51: Pixel array portion
51a: Pixel
61: Substrate
62: On-chip lens
65-1, 65-2: Signal extraction section
71-1, 71-2, 71: N+ semiconductor region
73-1, 73-2, 73: P+ semiconductor region
441-1, 441-2, 441: Isolation region
471-1, 472, 471: Isolation region

1. A light detection device comprising:
a semiconductor layer having a photoelectric conversion region defined by an isolation region including a groove, wherein
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.

2. The light detection device according to claim 1, wherein the first side portion is in a planar shape, and the second side portion is in a curved shape.

3. The light detection device according to claim 1, wherein a width of the second side portion in a same direction as a width of the first side portion is wider than the width of the first side portion in plan view.

4. The light detection device according to claim 1, wherein the first portion is provided on each of width directional opposite sides of the second portion in plan view.

5. The light detection device according to claim 1, wherein
the first portion extends in a first direction in plan view, and
the second portion extends in a second direction orthogonal to the first direction in plan view.

6. The light detection device according to claim 1, wherein the isolation region extends from, out of a first surface and a second surface of the semiconductor layer located on opposite sides to each other, a side of the second surface toward a side of the first surface.

7. The light detection device according to claim 1, further comprising:
a multilayer wiring layer provided on a side of a light entrance surface of the semiconductor layer; and
a microlens provided on an opposite side of the multilayer wiring layer to a side of the semiconductor layer.

8. A light detection device comprising:
a semiconductor layer having a photoelectric conversion region defined by an isolation region including a groove; and
two transfer transistors provided in the photoelectric conversion region, wherein
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.

9. An electronic apparatus comprising:
a light detection device;
an optical lens configured to cause image light from a subject to be formed as an image on an imaging plane of the light detection device; and
a signal processing circuit configured to apply signal processing to a signal outputted from the light detection device, wherein
the light detection device includes a semiconductor layer having a photoelectric conversion region defined by an isolation region including a groove,
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.

10. An electronic apparatus comprising:
a light detection device;
an optical lens configured to cause image light from a subject to be formed as an image on an imaging plane of the light detection device; and
a signal processing circuit configured to apply signal processing to a signal outputted from the light detection device, wherein
the light detection device includes
a semiconductor layer having a photoelectric conversion region defined by an isolation region including a groove, and
two transfer transistors provided in the photoelectric conversion region,
the isolation region includes a first portion and a second portion adjacent to each other with the semiconductor layer in between in plan view,
the semiconductor layer between the first portion and the second portion includes a first side portion on a side of the first portion and a second side portion on a side of the second portion, and
the first side portion and the second side portion are different in shape in cross-sectional view.
